(19) United States
(12) Patent Application Publication
(10) Pub. No.: US 2003/0189851 A1
(43) Pub. Date: Oct. 9, 2003

(54) Non-volatile, multi-level memory device

(76) Inventors: Sarah M. Brandenberger, Boise, ID (US); Kenneth K. Smith, Boise, ID (US); Kenneth J. Eldredge, Boise, ID (US); Andrew L. Van Brocklin, Corvallis, OR (US); Peter J. Fricke, Corvallis, OR (US)

Correspondence Address: HEWLETT-PACKARD COMPANY, Intellectual Property Administration, P.O. Box 272400, Fort collins, CO, 80527-2400, US

(21) Appl. No.: 10/120,118

(22) Filed: Apr. 9, 2002

(51) Int. Cl. G11C 7/00

(52) U.S. Cl. 365/200

(57) ABSTRACT

A read-only memory device has multiple layers, where a first layer is formed on a semiconductor substrate, and one or more additional layers are formed over the first layer. Each layer has multiple non-volatile memory cells that include a memory component connected between electrically conductive traces. A memory component indicates a resistance value when a potential is applied to a selected memory cell. A memory component can be formed with a resistor, a resistor in series with a control element, or an anti-fuse device in series with a diode. A memory device having memory components that include an anti-fuse device can be programmed after manufacture, where an anti-fuse device indicates a high resistance value corresponding to a logical one when the memory device is manufactured, and indicates a low resistance value corresponding to a logical zero when a junction of the anti-fuse device is penetrated to form an electrical connection.

### TECHNICAL FIELD

This invention relates to memory devices and, in particular, to a non-volatile, multi-level memory device.

### BACKGROUND

Conventional read-only memory (ROM) circuits are implemented as special-purpose integrated circuits for the permanent storage of program instructions and data. For example, a ROM circuit can be manufactured with specific instructions for the operation of a computer system.

Typically, a ROM circuit consists of an array of memory cells on a semiconductor, and each memory cell has a transistor that is fabricated to indicate a “one” or “zero” based on how the semiconductor is implanted to create the transistor. The data is permanently stored with a memory cell, and it cannot then be erased or altered electrically. Each of the transistors can be formed so as to have one of the two predetermined values. Additionally, a ROM circuit is fabricated as a single level device, where the array of memory cells are formed adjacent to each other over a semiconductor substrate.

A programmable ROM (PROM) circuit is designed to be programmed after the semiconductor chip has been manufactured. The memory cells of a PROM device are programmed with data (e.g., a “one” or a “zero”) when the instructions are burned into the chip. A mask ROM is encoded by selectively programming a threshold voltage level of each memory cell transistor in an array of transistors to one or two or more predetermined levels. This is accomplished by forming contacts that define the threshold voltage levels near the end of the manufacturing process. When a PROM device is programmed, the device can be implemented like a conventional ROM chip in that the data cannot be electrically altered.

Due to the costs of fabricating semiconductor devices, and the design of smaller integrated circuit-based electronic devices, there is an ever-present need to provide non-volatile memory circuits that take up less space, have improved memory storage capacity, and are inexpensive to manufacture.

### SUMMARY

A read-only memory device is described having multiple layers. A first layer of the memory device is formed on a semiconductor substrate, and one or more additional layers are formed over the first layer. Each layer has multiple non-volatile memory cells that include a memory component connected between electrically conductive traces.

The conductive traces in a particular layer are formed as rows of conductive material crossing over columns of conductive material. An individual memory cell is formed by connecting a memory component between a row of conductive material and a column of conductive material.

The layers of the memory device can be electrically insulated from each other with an insulation material, or the layers can share conductive traces between the layers. For example, a memory component in the first layer of the memory device, and a memory component in a second layer of the memory device can both be connected to the same row of conductive material, but connected to different columns of conductive material in each of the respective layers.

A memory component in a memory cell indicates a resistance value when a potential is applied to a selected memory cell. A memory component can be formed to include a resistor, a resistor in series with a control element, or an anti-fuse device in series with a diode. A memory device having memory components that include resistors are formed to have either a high resistance value corresponding to a logical one, or a low resistance value corresponding to a logical zero.

A memory device having memory components that include an anti-fuse device can be programmed after manufacture, where an anti-fuse device can indicate a high resistance value corresponding to a logical one when the memory device is manufactured, and then indicate a low resistance value corresponding to a logical zero when a junction of the anti-fuse device is penetrated to form an electrical connection.

### BRIEF DESCRIPTION OF THE DRAWINGS

The same numbers are used throughout the drawings to reference like features and components.

FIGS. 1A and 1B illustrate schematics of a non-volatile, multi-level memory device.

FIG. 2 illustrates a circuit diagram of a non-volatile memory array having memory cells that include a resistor.

FIG. 3 illustrates a circuit diagram of a non-volatile memory array having memory cells that include a resistor in series with a control element.

FIG. 4 illustrates a circuit diagram of a non-volatile memory array having memory cells that include an anti-fuse device in series with a diode.

FIG. 5 illustrates a non-volatile, multi-level memory semiconductor device having electrically insulated layers.

FIG. 6 illustrates a non-volatile, multi-level memory semiconductor device.

FIG. 7 is a flow diagram that describes methods for making a non-volatile, multi-level memory and/or logic device.

### DETAILED DESCRIPTION

Introduction

The following describes a non-volatile, multi-level memory device, and methods for making such a memory device. A multi-level read-only memory (ROM) device takes up less space than a conventional ROM device, yet provides more memory capacity. A multi-level ROM device can be utilized in small electronic devices and accommodates requests for smaller memory devices. Additionally, a memory device fabricated with resistive memory cells, rather than conventional transistor based memory cells, is less expensive to manufacture. Less expensive and smaller memory devices provide greater design flexibility for integrated circuit-based electronic devices.

Exemplary Multi-Level ROM Devices

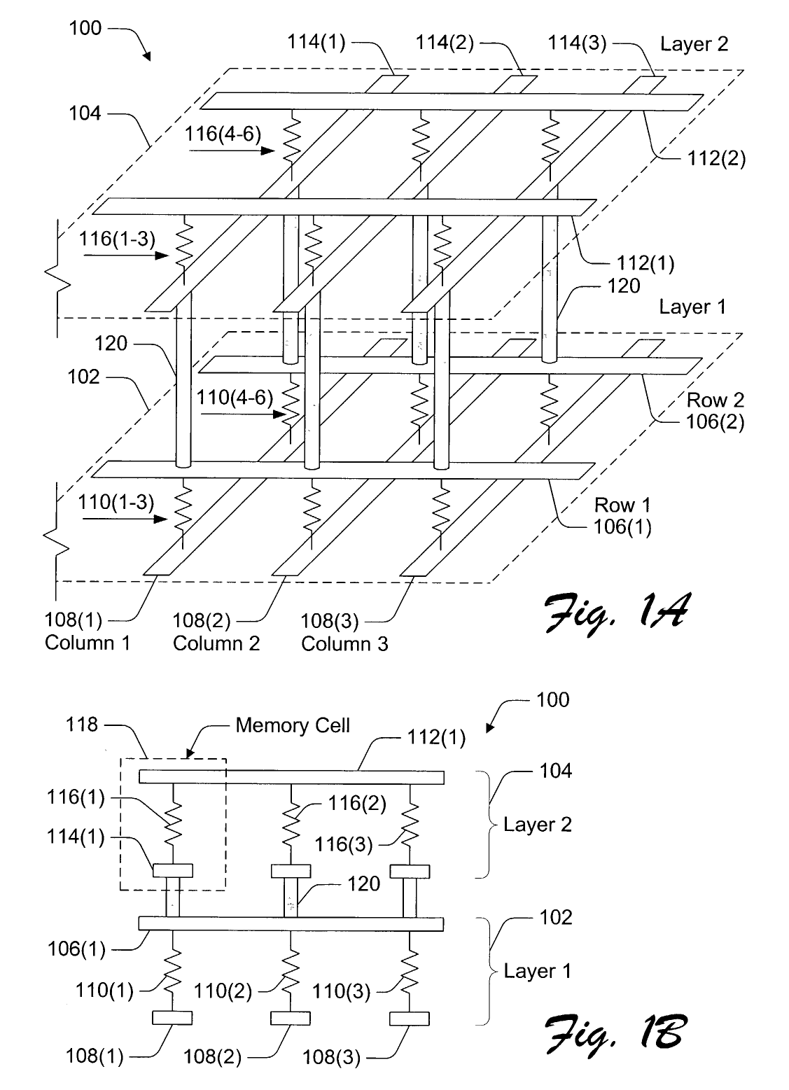

FIGS. 1A and 1B are schematics of a non-volatile, multi-level read-only memory (ROM) device 100. The schematics illustrate memory device 100 having two layers, a first layer 102 and a second layer 104. The first layer 102 of memory device 100 has conductive traces that are formed as rows of conductive material 106(1-2) crossing over columns of conductive material 108(1-3).

The first layer 102 also has memory components 110(1-6) illustrated as resistors in the schematic. Each memory component 110 is connected between a row of conductive material and a column of conductive material. For example, memory component 110(1) is connected between the row of conductive material 106(1) and the column of conductive material 108(1).

Similarly, the second layer 104 has conductive traces that are formed as rows of conductive material 112(1-2) crossing over columns of conductive material 114(1-3). Memory components 116(1-6) are connected between a row of conductive material and a column of conductive material, which is designated as a memory cell. For example, memory cell 118 includes a memory component 116(1) connected between the row of conductive material 112(1) and the column of conductive material 114(1).

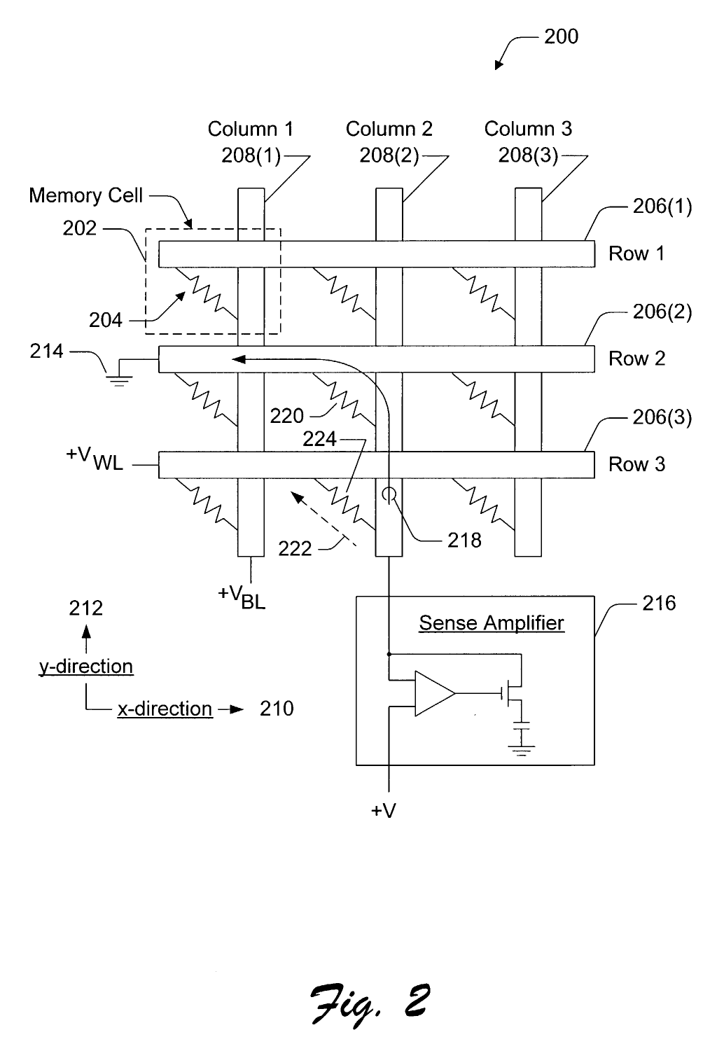

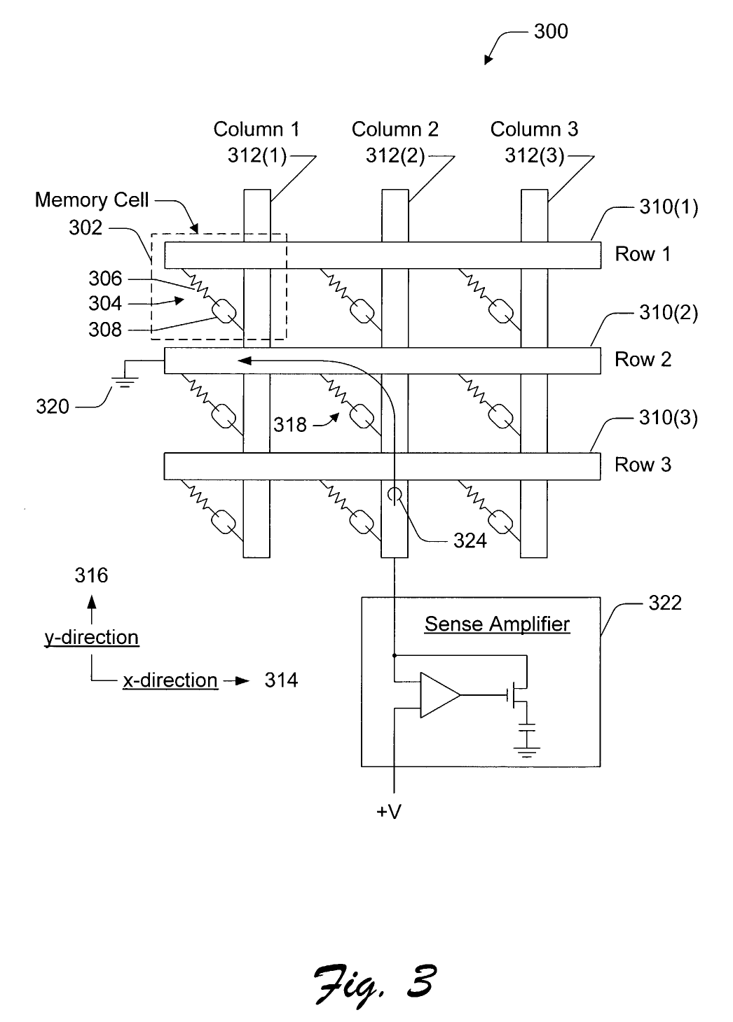

Each layer of memory device 100 has multiple memory cells, and each memory cell has a memory component. Each memory component (e.g., the resistors in FIG. 2) has a determinable resistance value when a potential is applied across the memory component. The resistance value of any one memory component at any cross-point can be designed to be relatively high (e.g. 10 Meg ohms), which translates to a logical bit value of one, or relatively low (e.g. 100K ohms), which translates to a logical bit value of zero. Correlating a relatively high resistance with a logical one, and a relatively low resistance with a logical zero is an implementation design choice. Accordingly, a relatively high resistance value can be defined as a logical zero and a relatively low resistance value can be defined as a logical one. In addition to a resistor memory component, each memory cell can include a control element in series with the resistor component which is described with reference to FIG. 3. A control element helps to discriminate between the different resistance values of the memory elements.

The memory cells of the first layer 102 and the memory cells of the second layer 104 are electrically insulated with a non-conductive material 120. Although shown in the schematic as individual insulators 120 between memory cells, the non-conductive material 120 can be formed as a solid layer between the first layer 102 and the second layer 104.

To simplify the description, FIGS. 1A and 1B show only two layers of memory device 100 and only a few memory cells per layer that include a memory component between, or at a cross point of, a row conductive trace and a column conductive trace. Those skilled in the art will appreciate that memory device 100 can be fabricated with any number of layers, and with any number of memory cells per layer to accommodate requests for smaller memory devices that provide more memory capacity.

Exemplary ROM Device with Resistors

FIG. 2 is a circuit diagram of a memory array 200 that represents one layer of a non-volatile, multi-level ROM device. An individual memory cell 202 has a resistor 204 memory component that is connected between a row of conductive material 206(1) and a column of conductive material 208(1).

The memory cells (i.e., a memory component connected between conductive traces) are arranged in rows extending along an x-direction 210 and in columns extending along a y-direction 212. Any additional layers of a ROM device would extend in the z-direction. Only a few memory cells are shown to simplify the description. In practice, a ROM device having multiple memory cell arrays 200 can be used. Additionally, the rows of conductive material 206 and the columns of conductive material 208 do not have to be fabricated perpendicular to each other. Those skilled in the art will recognize the various fabrication techniques and semiconductor design layouts that can be implemented to fabricate memory array 200.

The rows of conductive material 206 are traces that function as word lines extending along the x-direction 210 in the memory array 200. The columns of conductive material 208 are traces that function as bit lines extending along the y-direction 212 in the memory array 200. There can be one word line for each row of the array and one bit line for each column of the array. Each memory cell is located at a cross point of a corresponding word line and bit line, where a memory cell stores a bit of information which translates to a logical one, or a logical zero.

The resistance state of a selected memory cell can be sensed by applying a voltage to the memory cell and measuring the current that flows through the memory component in the memory cell. The resistance value is proportional to the sense current. During a read operation to determine the resistance value of a memory component in a memory cell, a row decoder (not shown) selects a word line 206(2) by connecting the word line to ground 214. A column decoder (not shown) selects a bit line 208(2) to be connected to a sense amplifier 216 that applies a positive voltage, identified as +V, to the bit line 208(2). The sense amplifier 216 senses the different resistance values of memory components in selected memory cells in the memory array 200.

All of the other unselected word lines (i.e., rows 206) are connected to a constant voltage source, identified as +V_{WL}, which is equivalent to the positive voltage +V. Additionally, all of the other unselected bit lines (i.e., columns 208) are connected to a constant voltage source, identified as +V_{BL}, which is also equivalent to the positive voltage +V. The constant voltage sources +V_{WL} and +V_{BL} can be supplied from an external circuit, or circuits, to apply an equipotential to prevent current loss. Those skilled in the art will recognize that voltage sources +V_{WL} and +V_{BL} do not have to be equipotential, and that current loss can be prevented with any number of circuit implementations.

In a non-volatile, multi-level memory array, the memory cells on a particular layer are coupled together through parallel paths. Applying equal potentials to the selected and unselected word and bit lines reduces parasitic currents. For example, a signal current 218 flows through resistor 220 when determining the resistance value of the memory component. If the equipotential voltage +V_{WL} applied to row 206(3) is less than selection voltage +V, an unwanted parasitic current 222 will flow through resistor 224.

The sense amplifier 216 can be implemented with sense amplifiers that include a differential, analog, or digital sense amplifier. Implementing a differential sense amplifier with a memory device is described in a U.S. Pat. No. 6,185,143 B1 to Perner et al. Implementing an analog sense amplifier with a memory device is described in a U.S. Pat. No. 6,128,239 to Perner. Implementing a digital sense amplifier with a memory device is described in a U.S. Pat. No. 6,188,615 B1 to Perner et al. All of the patents to Perner are assigned to the Hewlett-Packard Company.

Exemplary ROM Device with Resistors and Control Elements

FIG. 3 is a circuit diagram of a memory array 300 that represents one layer of a non-volatile, multi-level ROM device. In memory array 300, an individual memory cell 302 has a memory component 304 that is formed with a resistor 306 connected in series with a control element 308. The memory component 304 is connected between a row of conductive material 310(1) and a column of conductive material 312(1).

A control element 308 functions to allow the selection of particular memory cell of memory array 300. The control element 308 can be implemented with a linear or nonlinear resistor, a tunnel junction diode, a tunnel diode, or a Schottky, PN, or PIN semiconductor diode.

The memory cells (i.e., the memory components connected between conductive traces) are arranged in rows extending along an x-direction 314 and in columns extending along a y-direction 316. Any additional layers of a ROM or logic device would extend in the z-direction. Only a few memory cells are shown to simplify the description. In practice, a ROM or logic device having multiple memory cell arrays 300 can be used. Additionally, the rows of conductive material 310 and the columns of conductive material 312 do not have to be fabricated perpendicular to each other. Those skilled in the art will recognize the various fabrication techniques and semiconductor design layouts that can be implemented to fabricate memory array 300.

The rows of conductive material 310 are traces that function as word lines extending along the x-direction 314 in memory array 300. The columns of conductive material 312 are traces that function as bit lines extending along the y-direction 316 in memory array 300. There can be one word line for each row of the array and one bit line for each column of the array. Each memory cell is located at a cross point of a corresponding word line and bit line, where a memory cell stores a bit of information which translates to a logical one, or a logical zero.

The resistance state of a selected memory cell can be sensed by applying a voltage to the memory cell and measuring the current that flows through the memory component in the memory cell. For example, to determine the resistance value of memory component 318, word line 310(2) is connected to ground 320, and bit line 312(2) is connected to a sense amplifier 322 that applies a positive voltage, identified as +V, to the bit line 312(2). The sense amplifier 322 senses the resistance value of memory component 318 which is proportional to a signal current 324 that flows through memory component 318.

Exemplary ROM Device with Anti-Fuse Junction and Diode

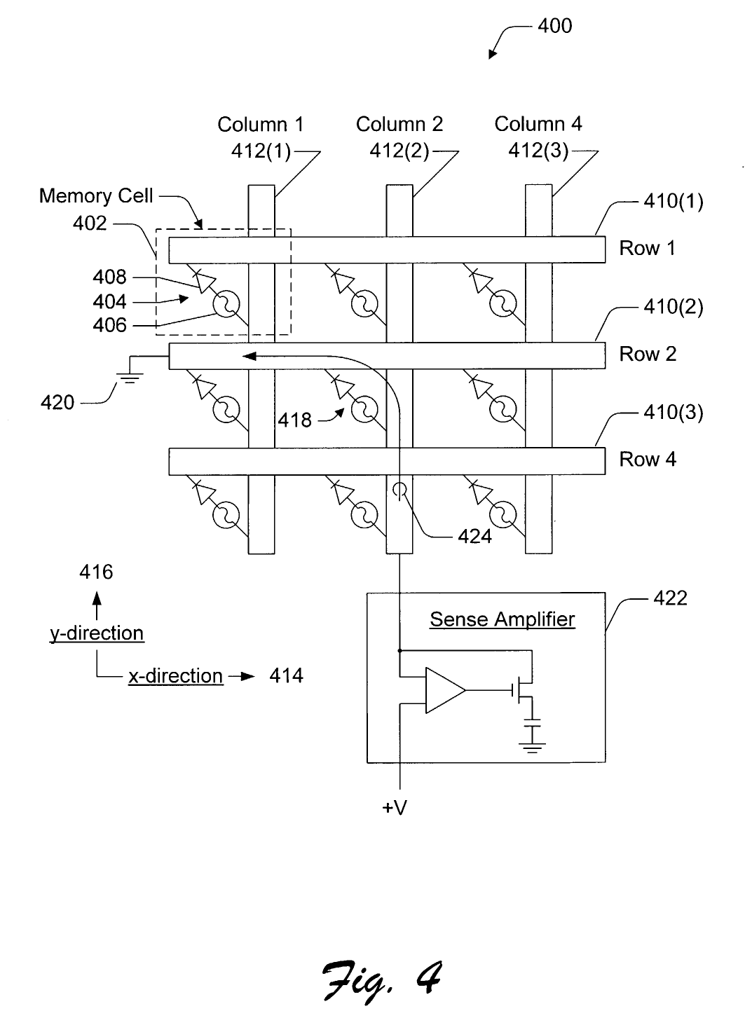

FIG. 4 is a circuit diagram of a memory array 400 that represents one layer of a non-volatile, multi-level ROM device. Additionally, memory array 400 can be implemented as a logic device, such as a one-time programmable gate array. The functionality of such a gate array would be similar to that of a field programmable gate array (FPGA) which is an integrated circuit that can be programmed after manufacture.

In memory array 400, an individual memory cell 402 has a memory component 404 that is formed with an anti-fuse device 406 connected in series with a diode 408. The memory component 404 is connected between a row of conductive material 410(1) and a column of conductive material 412(1). Anti-fuse device 406 is a tunnel-junction, one-time programmable device. The tunnel-junction of the anti-fuse device is a thin oxide junction that electrons “tunnel” through when a pre-determined, relatively high potential is applied across the anti-fuse device. The applied potential causes an electrical connection when the oxide junction is destroyed. Anti-fuse device 406 can be implemented with any number of available components and types of fuses or anti-fuses, such as a LeComber, Silicide, Tunnel Junction, Oxide Rupture, or any other similar fuse components.

Each memory cell of memory array 400 can be fabricated with an anti-fuse device that indicates a high resistance value when a relatively low voltage is applied across the anti-fuse device when reading a particular memory cell. Selected memory cells can be programmed by applying the relatively high potential across the anti-fuse devices in selected memory cells such that the anti-fuse devices indicate a low resistance when the relatively low voltage is applied across a particular memory cell. The anti-fuse devices can be utilized as programmable switches that allow memory array 400 to be implemented as a programmable logic device, similar to an FPGA. The anti-fuse devices can be utilized as both logic elements and as routing interconnects. Unlike traditional switching elements, the anti-fuse devices can be optimized to have a very low resistance once programmed which allows for high-speed interconnects and lower power levels.

The memory cells (i.e., a memory component connected between conductive traces) are arranged in rows extending along an x-direction 414 and in columns extending along a y-direction 416. Any additional layers of a ROM or logic device would extend in the z-direction. Only a few memory cells are shown to simplify the description. In practice, a ROM or logic device having multiple memory cell arrays 400 can be used. Additionally, the rows of conductive material 410 and the columns of conductive material 412 do not have to be fabricated perpendicular to each other. Those skilled in the art will recognize the various fabrication techniques and semiconductor design layouts that can be implemented to fabricate the memory array 400.

The rows of conductive material 410 are traces that function as word lines extending along the x-direction 414 in the memory array 400. The columns of conductive material 412 are traces that function as bit lines extending along the y-direction 416 in the memory array 400. There can be one word line for each row of the array and one bit line for each column of the array. Each memory cell is located between, or at a cross point of, a corresponding word line and bit line, where a memory cell stores a bit of information which translates to a logical one, or a logical zero.

The resistance state of a selected memory cell can be sensed by applying a voltage to the memory cell and measuring the current that flows through the memory component in the memory cell. For example, to determine the resistance value of memory component 418, word line 410(2) is connected to ground 420, and bit line 412(2) is connected to a sense amplifier 422 that applies a positive voltage, identified as +V, to the bit line 412(2). The sense amplifier 422 senses the resistance value of memory component 418 which is proportional to a signal current 424 that flows through memory component 418. The other unselected word lines (i.e., rows 410), and unselected bit lines (i.e., columns 412), do not require an equipotential applied as shown in memory array 200 (FIG. 2) because the diodes in the non-selected memory cells prevent any loss of current (e.g., parasitic currents).

Exemplary Multi-Level ROM Devices with Insulated Layers

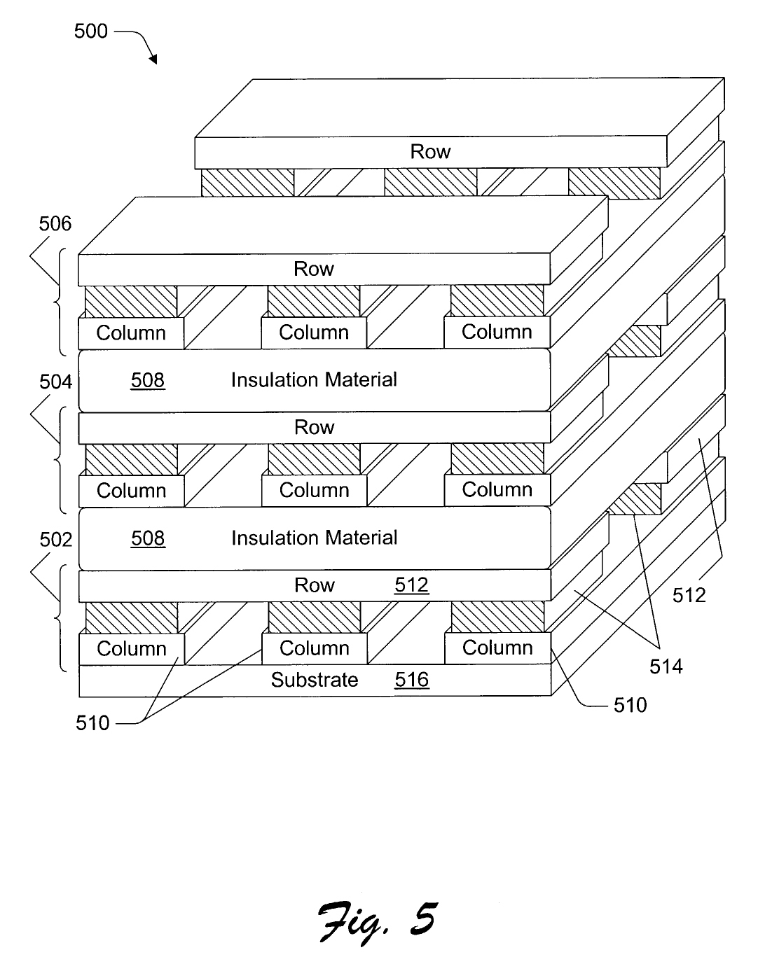

FIG. 5 illustrates a section of a non-volatile, multi-level ROM semiconductor device 500 having electrically insulated layers 502, 504, and 506. Each layer is insulated from the next with an insulation material 508. An individual layer, such as layer 502 for example, has columns of conductive material 510, rows of conductive material 512, and memory components 514.

The first layer 502 is formed on a substrate layer 516 of the semiconductor device 500. The substrate layer 516 can be any construction of semiconductive material that is a supporting structure for the device 500. Each additional layer of the device 500 is formed on the preceding layer. For example, layer 504 is formed over layer 502, and layer 506 is formed over layer 504. Although the semiconductor device 500 is shown with only three layers, those skilled in the art will appreciate that the device can be fabricated with any number of layers, and with any number of memory cells per layer.

The columns of conductive material 510 and the rows of conductive material 512 can be fabricated with electrically conductive material such as copper or aluminum, or with alloys or doped silicon. The memory components 514 can be implemented with an electrically resistive material, such as an oxide, that forms a resistor memory component as shown in FIG. 2, a resistor memory component in series with a control element as shown in FIG. 3, or an anti-fuse junction in series with a diode as shown in FIG. 4. The insulation layers 508 can be formed with a silicon dioxide material. Those skilled in the art will recognize that many different combinations of materials and designs are available to fabricate the semiconductor device 500.

Exemplary Multi-Level ROM Devices with Shared Layers

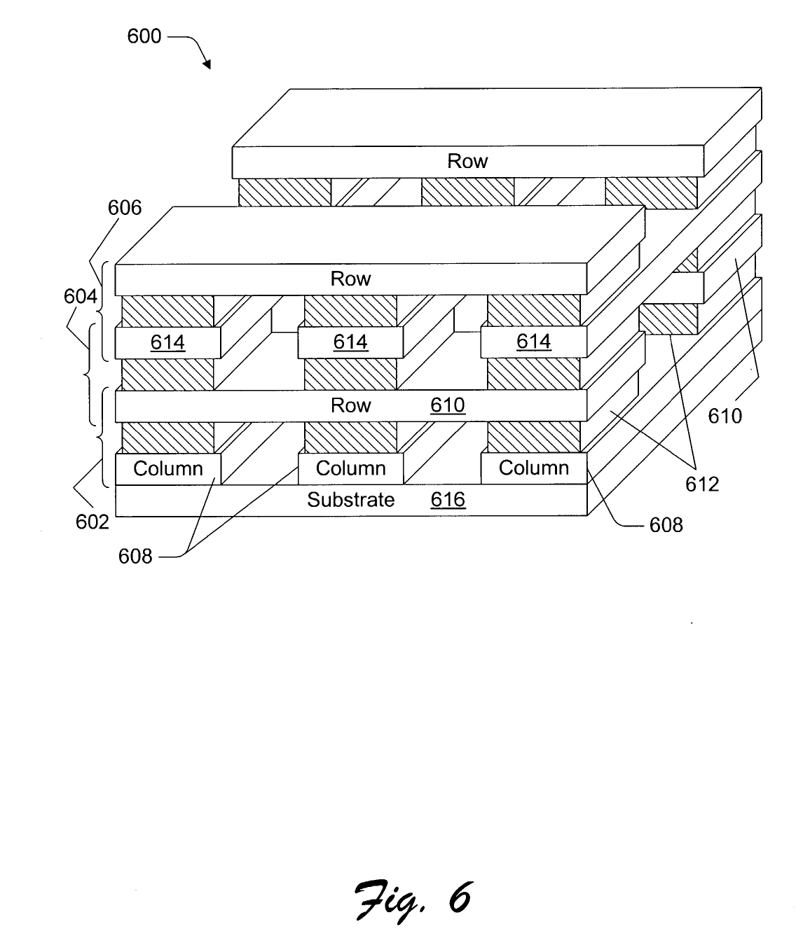

FIG. 6 illustrates a section of a non-volatile, multi-level ROM semiconductor device 600 having layers 602, 604, and 606. An individual layer, such as layer 602 for example, has columns of conductive material 608, rows of conductive material 610, and memory components 612. Each layer shares components with one or more other layers of the device 600. For example, layers 602 and 604 share common rows of conductive material 610, and layers 604 and 606 share common columns of conductive material 614.

The first layer 602 is formed on a substrate layer 616 of the semiconductor device 600. The substrate layer 616 can be any construction of semiconductive material that is a supporting structure for the device 600. Each additional layer of the device 600 is formed on the preceding layer. For example, layer 604 is formed over layer 602, and layer 606 is formed over layer 604. Although the semiconductor device 600 is shown with only three layers, those skilled in the art will appreciate that the device can be fabricated with any number of layers, and with any number of memory cells per layer.

The columns of conductive material 608, 614 and the rows of conductive material 610 can be fabricated with electrically conductive material such as copper or aluminum, or with alloys or doped silicon. The memory components 612 can be implemented with an electrically resistive material, such as an oxide, that forms a resistor memory component as shown in FIG. 2, a resistor memory component in series with a control element as shown in FIG. 3, or an anti-fuse junction in series with a diode as shown in

FIG. 4. Those skilled in the art will recognize that many different combinations of materials and designs are available to fabricate the semiconductor device 600.

Methods for Making Non-Volatile, Multi-Level Devices

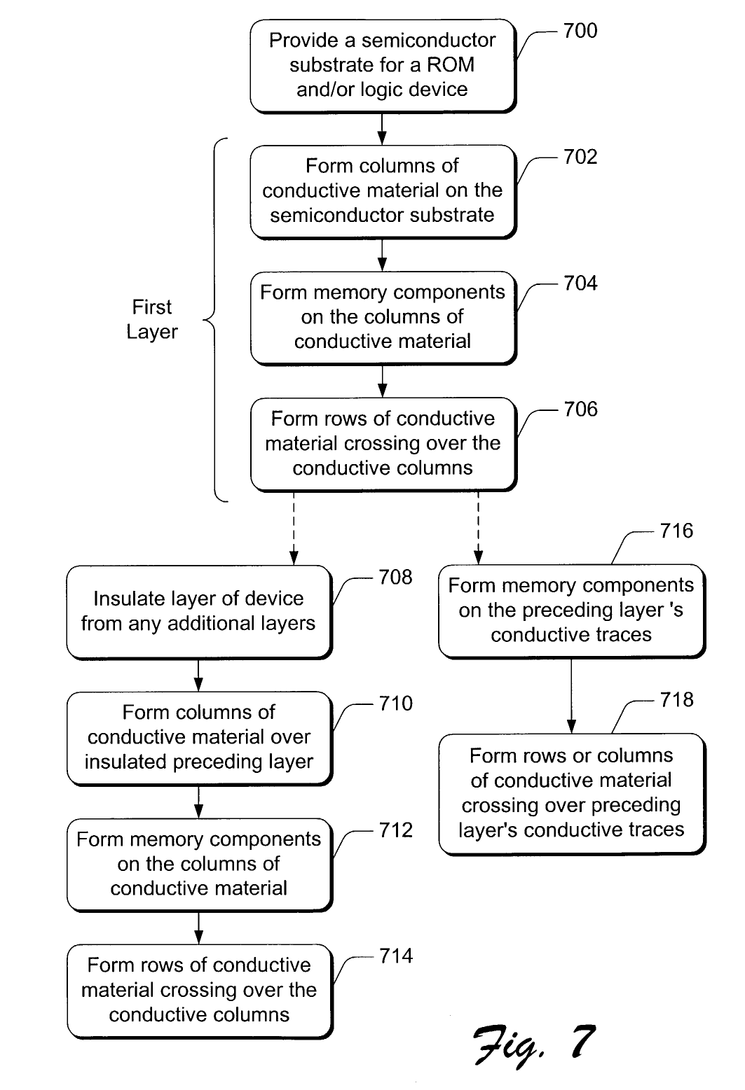

FIG. 7 illustrates methods for making non-volatile, multi-level ROM and/or logic devices. The order in which the method is described is not intended to be construed as a limitation.

At block 700, a semiconductor substrate is provided upon which the multi-level ROM or logic device is fabricated. At block 702, columns of conductive material are formed on the semiconductor substrate. The columns of conductive material are formed by either a copper damascene process, or by an aluminum or other metal deposition process.

At block 704, memory components are formed on the columns of conductive material. The memory components are formed by growth or deposition of aluminum oxide, or other similar insulating and/or tunneling material. To form a series element, a next component can be grown or deposited atop the insulating and/or tunneling barrier of the previous memory component.

At block 706, rows of conductive material are formed over the memory components such that the rows of conductive material cross over the columns of conductive material formed at block 702. The rows of conductive material are also formed by the process described to form the columns of conductive material.

An individual memory cell is created when a memory component is connected between a row of conductive material and a column of conductive material. A memory component can be formed as a resistor, as a resistor in series with a control element, or as an anti-fuse junction in series with a diode. Additionally, performing blocks 702 through 706 forms a first layer of a non-volatile, multi-level ROM and/or logic device. Each layer of such a device includes rows of conductive material crossing over columns of conductive material, wherein a non-volatile memory cell includes connecting a memory component between a row of conductive material and a column of conductive material.

At block 708, an electrically insulating material is formed over the first layer to insulate the first layer from any additional layers of the multi-level ROM and/or logic device. At block 710, columns of conductive material are formed on the insulating layer. At block 712, memory components are formed on the columns of conductive material. At block 714, rows of conductive material are formed over the memory components such that the rows of conductive material cross over the columns of conductive material formed at block 710. Blocks 708 through 714 are repeated for each additional layer of the memory and/or logic device, such that each additional layer is formed on a preceding layer.

As an alternative to forming an insulation layer over the first layer at block 708, memory components for an additional layer are formed on the conductive traces (e.g., rows or columns) of a preceding layer at block 716. For example, memory components for a second layer are formed on the first layer's rows of conductive material formed at block 706.

At block 718, rows or columns of conductive material are formed over the memory components such that the rows or columns of conductive material cross over the conductive traces formed at block 716. For example, columns of conductive material would be formed at block 718 for a second layer, such that the columns of conductive material cross over the rows of conductive material formed at block 706. Blocks 716 and 718 are repeated for each additional layer of the memory and/or logic device, such that each additional layer is formed on a preceding layer and shares components (e.g., rows or columns) of the preceding layer.

Conclusion

A non-volatile, multi-level ROM device takes up less space than a conventional memory device, yet can provide more memory capacity. A multi-level ROM device fabricated with memory cells having resistors, or resistors in series with control elements, is inexpensive to manufacture and offers design flexibility for integrated circuit-based electronic devices. Additionally, a multi-level ROM device fabricated with memory cells having an anti-fuse junction in series with a diode can be implemented as a logic device.

Although the invention has been described in language specific to structural features and/or methodological steps, it is to be understood that the invention defined in the appended claims is not necessarily limited to the specific features or steps described. Rather, the specific features and steps are disclosed as preferred forms of implementing the claimed invention.

1. A non-volatile read-only memory device, comprising:
a semiconductor substrate;
a first layer disposed over the semiconductor substrate, the first layer including a plurality of memory cells; and
one or more additional layers disposed over the first layer, each additional layer including a plurality of memory cells.

2. A non-volatile read-only memory device as recited in claim 1, wherein an individual layer includes a plurality of conductive traces, and wherein an individual memory cell includes a memory component connected between a first conductive trace and a second conductive trace in a respective layer.

3. A non-volatile read-only memory device as recited in claim 1, wherein an individual layer includes a plurality of conductive traces formed as rows of conductive material configured to cross over columns of conductive material, and wherein an individual memory cell includes a memory component connected between a row of conductive material and a column of conductive material.

4. A non-volatile read-only memory device as recited in claim 1, wherein an individual memory cell includes a memory component formed with electrically resistive material configured to indicate a resistance value when a potential is applied to the individual memory cell.

5. A non-volatile read-only memory device as recited in claim 1, wherein an individual memory cell includes a resistor.

6. A non-volatile read-only memory device as recited in claim 1, wherein an individual memory cell includes a resistor in series with a control element.

7. A non-volatile read-only memory device as recited in claim 1, wherein an individual memory cell includes an anti-fuse device in series with a diode.

8. A non-volatile read-only memory device as recited in claim 1, wherein an individual memory cell includes an anti-fuse junction in series with a diode, the anti-fuse junction being configured to indicate a resistance value corresponding to a logical one when a potential is applied to the individual memory cell.

9. A non-volatile read-only memory device as recited in claim 1, wherein an individual memory cell includes an anti-fuse junction in series with a diode, the anti-fuse junction being configured to indicate a resistance value corresponding to a logical zero when a potential is applied to the individual memory cell.

10. A non-volatile read-only memory device as recited in claim 1, wherein an individual memory cell includes an anti-fuse junction in series with a diode, the anti-fuse junction being configured to indicate a first resistance value corresponding to a logical one when the memory device is manufactured, and further configured to indicate a second resistance value corresponding to a logical zero when the anti-fuse junction is penetrated to form an electrical connection.

11. A non-volatile read-only memory device as recited in claim 1, wherein an individual layer includes a plurality of conductive traces, and wherein the first layer and a second layer have common conductive traces.

12. A non-volatile read-only memory device as recited in claim 1, wherein:
an individual layer includes a plurality of conductive traces formed as rows of conductive material configured to cross over columns of conductive material;
a memory component in the first layer is connected between a row of conductive material and a first column of conductive material; and
a memory component in a second layer is connected between the row of conductive material and a second column of conductive material.

13. A non-volatile read-only memory device as recited in claim 1, wherein the first layer is electrically insulated from a second layer.

14. A non-volatile read-only memory device as recited in claim 1, wherein the memory cells of an individual layer are electrically insulated from the memory cells of any additional layer.

15. A read-only memory device, comprising:
a plurality of layers having non-volatile memory cells, an individual layer comprising:
electrically conductive traces; and
memory components configured to indicate a resistance value when a potential is applied to a selected non-volatile memory cell, wherein an individual non-volatile memory cell includes a memory component connected between a first electrically conductive trace in the individual layer and a second electrically conductive trace in the individual layer.

16. A read-only memory device as recited in claim 15, wherein the electrically conductive traces are formed as rows of conductive material configured to intersect columns of conductive material, and wherein an individual non-volatile memory cell includes a memory component connected between a row of conductive material and a column of conductive material.

17. A read-only memory device as recited in claim 15, wherein the memory components are formed with electrically resistive material.

18. A read-only memory device as recited in claim 15, wherein an individual memory component is a resistor.

19. A read-only memory device as recited in claim 15, wherein an individual memory component is a resistor is series with a control element.

20. A read-only memory device as recited in claim 15, wherein the memory components include resistors.

21. A read-only memory device as recited in claim 15, wherein a first memory component is formed with an electrically resistive material configured to indicate a first resistance value corresponding to a logical one, and a second memory component is formed with an electrically resistive material configured to indicate a second resistance value corresponding to a logical zero.

22. A read-only memory device as recited in claim 15, wherein an individual memory component includes an anti-fuse device in series with a diode.

23. A read-only memory device as recited in claim 15, wherein an individual memory component is formed with an anti-fuse junction in series with a diode, the anti-fuse junction being configured to indicate a first resistance value corresponding to a logical one when the memory device is manufactured, and further configured to indicate a second resistance value corresponding to a logical zero when the anti-fuse junction is penetrated to form an electrical connection.

24. A read-only memory device as recited in claim 15, wherein the electrically conductive traces are formed as rows of conductive material configured to intersect columns of conductive material, and wherein the rows of conductive material are common to the individual layer and to a second layer.

25. A method, comprising:
forming a first layer;
forming one or more additional layers over the first layer;
wherein forming an individual layer comprises:
forming a plurality of electrically conductive traces; and
forming a plurality of non-volatile memory cells, individual memory cells being formed by connecting a memory component between a first electrically conductive trace in the individual layer and a second electrically conductive trace in the individual layer.

26. A method as recited in claim 25, further comprising providing a semiconductor substrate, and forming the first layer on the semiconductor substrate.

27. A method as recited in claim 25, wherein forming the plurality of electrically conductive traces comprises forming rows of conductive material crossing over columns of conductive material, and wherein forming a non-volatile memory cell comprises connecting a memory component between a cross-point of a row of conductive material and a column of conductive material.

28. A method as recited in claim 25, wherein the first layer and a second layer have common electrically conductive traces.

29. A method as recited in claim 25, wherein:
forming the plurality of electrically conductive traces comprises forming rows of conductive material crossing over columns of conductive material; and
forming the plurality of non-volatile memory cells comprises connecting a memory component in the first layer between a row of conductive material and a first column of conductive material, and connecting a memory component in a second layer between the row of conductive material and a second column of conductive material.

30. A method as recited in claim 25, further comprising forming memory components with electrically resistive material that indicates a resistance value when a potential is applied to a selected non-volatile memory cell.

31. A method as recited in claim 25, further comprising forming a memory component with a resistor.

32. A method as recited in claim 25, further comprising forming a memory component with a resistor is series with a control element.

33. A method as recited in claim 25, further comprising forming a memory component with an anti-fuse device in series with a diode.

34. A method as recited in claim 25, further comprising forming memory components with an anti-fuse junction in series with a diode, the anti-fuse junction being formed to indicate a resistance value corresponding to a logical one when a potential is applied to a selected non-volatile memory cell.

35. A method as recited in claim 25, further comprising forming memory components with an anti-fuse junction in series with a diode, the anti-fuse junction being formed to indicate a resistance value corresponding to a logical zero when a potential is applied to a selected non-volatile memory cell.

36. A method as recited in claim 25, further comprising forming memory components with an anti-fuse junction in series with a diode, the anti-fuse junction being formed to indicate a first resistance value corresponding to a logical one when a non-volatile memory cell is formed, and the anti-fuse junction being formed to indicate a second resistance value corresponding to a logical zero when the anti-fuse junction is penetrated to form an electrical connection.

37. A method as recited in claim 25, further comprising electrically insulating the first layer from an additional layer with a non-conductive material.

38. A method of making a non-volatile read-only memory device comprising the method recited in claim 25.

39. A method of making a programmable logic device comprising the method recited in claim 25.

40. A method of making a programmable logic device, comprising:
providing a semiconductor substrate;
forming a first layer on the semiconductor substrate;
forming one or more additional layers over the first layer;
wherein forming an individual layer comprises:
forming a plurality of conductive traces with electrically conductive material; and
forming a plurality of non-volatile memory cells, individual memory cells being formed by connecting an anti-fuse junction in series with a diode between a first conductive trace in the individual layer and a second conductive trace in the individual layer.

41. A method of making a programmable logic device as recited in claim 40, wherein forming the plurality of conductive traces comprises forming rows of conductive material crossing over columns of conductive material, and wherein forming a non-volatile memory cell comprises connecting an anti-fuse junction in series with a diode between a row of conductive material and a column of conductive material.

42. A method of making a programmable logic device as recited in claim 40, wherein the first layer and a second layer have common conductive traces.

43. A method of making a programmable logic device as recited in claim 40, wherein forming the plurality of conductive traces comprises forming rows of conductive material crossing over columns of conductive material, and wherein forming the plurality of non-volatile memory cells comprises:
connecting an anti-fuse junction in series with a diode between a row of conductive material and a first column of conductive material in the first layer; and
connecting an anti-fuse junction in series with a diode between the row of conductive material and a second column of conductive material in the second layer.

44. A method of making a programmable logic device as recited in claim 40, wherein the individual memory cells are formed with an anti-fuse junction in series with a diode, the anti-fuse junction being formed to indicate a first resistance value corresponding to a logical one when a non-volatile memory cell is formed, and the anti-fuse junction being formed to indicate a second resistance value corresponding to a logical zero when the anti-fuse junction is penetrated to form an electrical connection.

45. A method of making a programmable logic device as recited in claim 40, further comprising electrically insulating the first layer from an additional layer with a non-conductive material.
